(19) United States
(12) Patent Application Publication
(10) Pub. No.: US 2005/0012107 A1
(43) Pub. Date: Jan. 20, 2005

(54) [LED DEVICE ]

(76) Inventors: SHIH-CHANG SHEI, TAINAN (TW); JINN-KONG SHEU, TAINAN COUNTY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/708,225

(22) Filed: Feb. 18, 2004

(30) Foreign Application Priority Data
Jul. 17, 2003 (TW) 92119488

(51) Int. Cl. H01L 33/00

(52) U.S. Cl. 257/98

(57) ABSTRACT

An LED device is described, including a substrate, a first doped layer of a first conductivity type, a light emitting layer, a second doped layer of a second conductivity, and two electrodes. The first doped layer is disposed on the substrate, the light emitting layer is disposed on a portion of the first doped layer, and the second doped layer is disposed on the light emitting layer. The first and the second doped layers and the light emitting layer together constitute an active layer. The active layer has rough sidewalls capable of preventing total reflection of the side light incident thereto. The two electrodes are disposed on the first doped layer and the second doped layer, respectively.

### CROSS REFERENCE TO RELATED APPLICATIONS

This application claims the priority benefit of Taiwan application serial no. 92119488, filed on Jul. 17, 2003.

### BACKGROUND OF INVENTION

1. Field of the Invention

The present invention relates to a semiconductor device structure, and more particularly, to an LED (Light Emitting Diode) device structure.

2. Description of the Related Art

The LED device constituted by a semiconductor material of a III-V group compound is one kind of wide-bandgap light emitting device. The spectrum of LED devices covers a range from the infrared to the ultraviolet and almost includes all bands of the visible light. Recently, along with the fast development of the high-brightness blue/green GaN-LED, the full-color LED display, the white light LED and the LED traffic light become more practical in their application fields, and the applications of other types of LED are well accepted.

FIG. 1 is a schematic sectional view of a conventional LED device, and FIG. 2A is a schematic top view of the LED device shown in FIG. 1, wherein FIG. 1 corresponds to the I-I″ sectional view of the device. As shown in FIG. 1 and FIG. 2A, the conventional LED device includes a substrate 100, an N-doped layer 110, a light emitting layer 120 and a P-doped layer 130 which three are sequentially stacked and defined into a block shape to serve as an active layer 133, and an anode 140 on the P-doped layer 130 and a cathode 150 on the N-doped layer 110. The light emitting efficiency of the LED device is dependent on the quantum efficiency of the light emitting layer 120 and the light extraction efficiency of the device. The methods for improving the quantum efficiency mainly focus on improving the crystallinity of the light emitting layer 120 and the structural design of the same. The key point for improving the light extraction efficiency is to reduce the energy loss due to the total reflection of the light emitted from the light emitting layer 120 inside the LED.

In order to cope with the total reflection problem, roughing the light emitting surface of the LED is an effective way, and it is usually performed in a later process. However, as shown in FIG. 2A and FIG. 2B, wherein FIG. 2B is a schematic magnified view of section II-II″ of the LED device shown in FIG. 2A, since the active layer 133 has smooth sidewalls, most of the side lights emitted by the light emitting layer 120 are totally reflected by the sidewalls to cause a big energy loss. That is, the LED package can only utilize the light emitted from the light emitting surface, but cannot further utilize the light incident to the sidewalls to further improve its total external quantum efficiency.

### SUMMARY OF INVENTION

In the light of the above problems, it is a primary object of the present invention to provide an LED device whose active layer has rough sidewalls capable of reducing the energy loss of the side light emitted by the light emitting layer.

The LED device provided by the present invention comprises a substrate, a first doped layer of a first conductivity type, a light emitting layer, a second doped layer of a second conductivity type, and two electrodes. The first doped layer is disposed on the substrate, the light emitting layer is disposed on a portion of the first doped layer, and the second doped layer is disposed on the light emitting layer. The first and the second doped layers and the light emitting layer together constitute an active layer. The active layer has rough sidewalls capable of preventing total reflection of the side light. The two electrodes are disposed on the first doped layer and the second doped layer, respectively.

In addition, in the LED device of the present invention mentioned above, the top surface of the second doped layer can also be roughed, so as to reduce the energy loss due to the total reflection of the front light emitted by the light emitting layer inside the LED.

Since the active layer of the LED device according to the present invention has rough sidewalls, the side light is not totally reflected by the sidewalls. Therefore, the energy loss of the side light emitted by the light emitting layer can be reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic sectional view of a conventional LED device.

FIG. 2A is a schematic top view of the conventional LED device shown in FIG. 1.

FIG. 2B is a schematic magnified view of section II-II′ of the conventional LED device.

FIG. 3A is a schematic top view of an LED device according to a preferred embodiment of the present invention.

FIG. 3B is a schematic magnified view of section III-III″ of the LED device shown in FIG. 3A.

FIG. 3C is a schematic sectional view illustrating the result of further roughing the active layer surface of the LED device.

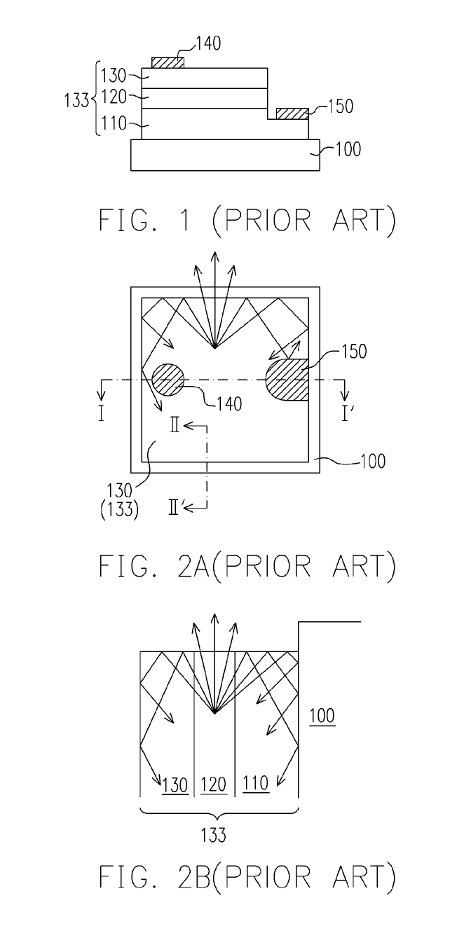

### DETAILED DESCRIPTION

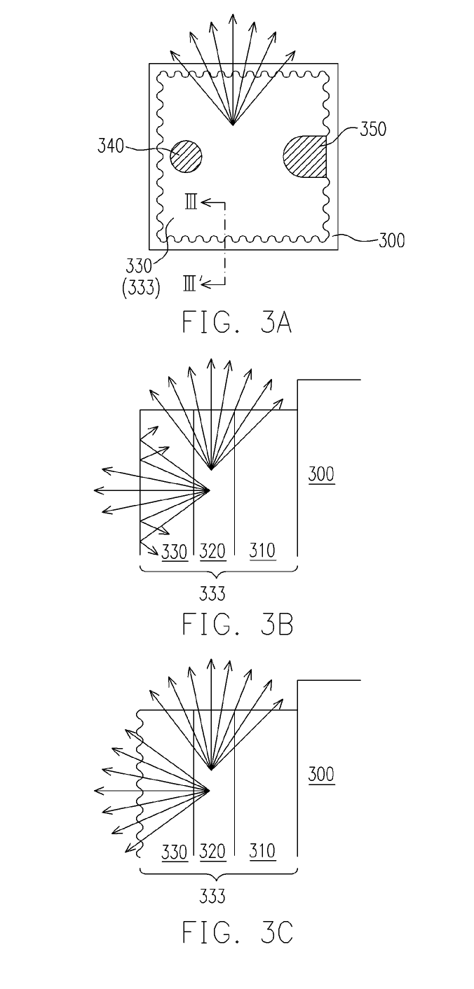

Referring to both FIG. 3A and FIG. 3B, which schematically show a top view of the LED device according to the preferred embodiment of the present invention and a magnified view of section III-III″ of the same, respectively. As shown in FIG. 3A and FIG. 3B, the LED device comprises a substrate 300, an N-doped layer 310, a light emitting layer 320, a P-doped layer 330, an anode 340, and a cathode 350. The N-doped layer 310 is disposed on the substrate 300, the light emitting layer 320 is disposed on a portion of the N-doped layer 310, and the P-doped layer is disposed on the light emitting layer 320. The P-doped layer 330, the light emitting layer 320, and the N-doped layer 320 together constitute an active layer 333, having rough sidewalls capable of preventing total reflection of the light incident to the sidewalls (Refer to FIG. 3A). The anode 340 and the cathode 350 are disposed on the P-doped layer 330 and the N-doped layer 310, respectively.

The substrate 300 mentioned above is, for example, a sapphire substrate. The N-doped layer 310, the light emitting layer 320, and the P-doped layer 330 are made from a semiconductor material of a III-V group compound, such as GaN, GaP, or GaAsP. The light emitting layer 320 is, for example, a light emitting layer having a structure of single or multiple quantum wells, so as to improve the light emitting efficiency. The anode 340 and the cathode 350 are made from a metallic material, such as Al.

The N-doped layer 310, the light emitting layer 320, and the P-doped layer 330 having rough sidewalls as mentioned above are formed by stacking three corresponding layers with continuous epitaxy of the same III-V group compound and defining them via a lithography process and a subsequent etching process. Specifically, after an N-doped layer, a light emitting layer and a P-doped layer are sequentially formed via a continuous epitaxy process, a lithography process is performed. A photomask having a rectangular pattern with rough edges thereon is used in the lithography process to form a rectangular photoresist pattern with the same rough edges on the P-doped layer. The shape of the rough edges of the rectangular pattern on the photomask or the rectangular photoresist pattern is the same as that of the P-doped layer 330 shown in FIG. 3A, i.e., a wavelike shape. The wavelike shape may be considered as the combination of a plurality of semicircular bumps. Then, the rectangular photoresist pattern with rough edges is used as a mask to anisotropically etch the P-doped layer, the light emitting layer and the N-doped layer sequentially, so as to form an active layer 333 having rough sidewalls, which is called a MESA. Since the active layer 333 is formed by using a photoresist pattern with rough edges as an etching mask in an anisotropic etching process, a plurality of pillar-shaped bumps, such as the semicircular pillar-shaped bumps shown in FIG. 3A and FIG. 3B, are formed on the sidewalls of the active layer 333. In other words, it is seen from the top view (FIG. 3A) that a plurality of small semicircular bumps are formed on the edges of the top surface of the P-doped layer 330, wherein each small semicircular bump is the top surface of an aforementioned semicircular pillar-shaped bump. In addition, because of the mechanism of the anisotropic etching process, the two side edges of the section III-III′ of the active layer 333 perpendicular to the top surface of the same are shaped as straight lines, as shown in FIG. 3B.

Moreover, depending on the variations of the edge shape of the pattern on the photomask, the pillar-shaped bump formed on the sidewalls of the active layer 333 may be a triangular pillar-shaped bump, a tetragonal pillar-shaped bump, a polygonal pillar-shaped bump, or even an irregular pillar-shaped bump.

By the way, in the MESA mentioned above, the P-doped layer 330, the light emitting layer 320, and part thickness of the N-doped layer 310 on the area where the cathode 350 is to be formed are removed, so that the cathode 350 can be coupled to the N-doped layer 310.

Furthermore, referring to FIG. 3C and FIG. 3B simultaneously, after the sidewall roughing process implemented with the patterning method mentioned above is completed, another roughing process may be performed to the top surface of the P-doped layer 330, so as to reduce the energy loss due to the total reflection of the front light emitting by the light emitting layer 320.

Since the active layer of the LED device according to the present invention has rough sidewalls, the side light is not totally reflected by the sidewalls, and the energy loss of the side light emitted by the light emitting layer can be reduced.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

1. An LED device, comprising:
a substrate;
a first doped layer of a first conductivity type on the substrate;
a light emitting layer on a portion of the first doped layer;
a second doped layer of a second conductivity type on the light emitting layer, wherein the second doped layer, the light emitting layer, and the first doped layer together constitute an active layer, and the active layer has a rough sidewall capable of preventing total reflection of a light incident to the sidewall; and
two electrodes on the first doped layer and the second doped layer, respectively.

2. The LED device of claim 1, wherein the sidewall of the active layer has a plurality of pillar-shaped bumps thereon resulting in the roughness thereof.

3. The LED device of claim 2, wherein the pillar-shaped bumps comprise a plurality of semicircular pillar-shaped bumps.

4. The LED device of claim 1, wherein the second doped layer comprises a rough top surface.

5. The LED device of claim 1, wherein the substrate comprises a sapphire substrate.

6. The LED device of claim 1, wherein the first doped layer, the light emitting layer and the second doped layer are constituted of a semiconductor material of a III-V group compound.

7. The LED device of claim 6, wherein the III-V group compound is selected from the group consisting of GaN, GaP, and GaAsP.

8. The LED device of claim 1, wherein the light emitting layer comprises a quantum well-type light emitting layer.

9. The LED device of claim 1, wherein the first doped layer is an N-doped layer, and the second doped layer is a P-doped layer.

10. The LED device of claim 1, wherein the first doped layer is a P-doped layer, and the second doped layer is an N-doped layer.

11. An LED device, comprising:
a substrate;
an active layer on the substrate, wherein the active layer comprises an N-doped layer, a P-doped layer and a light emitting layer disposed in between, and the active layer has a rough sidewall capable of preventing total reflection of a light incident to the sidewall; and
two electrodes on the first doped layer and the second doped layer, respectively.

12. The LED device of claim 11, wherein the sidewall of the active layer has a plurality of pillar-shaped bumps thereon resulting in the roughness thereof.

13. The LED device of claim 12, wherein the pillar-shaped bumps comprise a plurality of semicircular pillar-shaped bumps.

14. The LED device of claim 11, wherein the active layer comprises a rough top surface.

15. The LED device of claim 11, wherein the substrate comprises a sapphire substrate.

16. The LED device of claim 11, wherein the N-doped layer, the light emitting layer, and the P-doped layer are constituted of a semiconductor material of a III-V group compound.

17. The LED device of claim 16, wherein the III-V group compound is selected from the group consisting of GaN, GaP, and GaAsP.

18. The LED device of claim 11, wherein the light emitting layer comprises a quantum well-type light emitting layer.
